(19) United States
(12) Patent Application Publication
(10) Pub. No.: US 2003/0180450 A1
(43) Pub. Date: Sep. 25, 2003

(54) System and method for preventing breaker failure

(76) Inventors: Jerry D. Kidd, Granbury, TX (US); Craig D. Harrington, Cleburne, TX (US); Daniel N. Hopkins, Fort Worth, TX (US)

Correspondence Address: J. Robert Brown, Jr., HUNTON & WILLIAMS, Energy Plaza, 30th Floor, 1601 Bryan Street, Dallas, TX, 75201-3402, US

(21) Appl. No.: 10/103,725

(22) Filed: Mar. 22, 2002

(51) Int. Cl. C23C 16/00

(52) U.S. Cl. 427/99; 427/96; 427/97

(57) ABSTRACT

A method for plasma plating circuit breaker components to prevent circuit breaker failure is provided. The method includes positioning a circuit breaker component of a circuit breaker within a vacuum chamber and positioning a depositant in an evaporation source within the vacuum chamber. The method further provides for applying a dc signal to the circuit breaker component and applying a radio frequency signal to the circuit breaker component. The method also includes heating the depositant to a temperature at or above the melting point of the depositant to generate a plasma in the vacuum chamber.

### TECHNICAL FIELD OF THE INVENTION

This invention relates in general to the field of deposition technology for plating and coating materials and more particularly, but not by way of limitation, to a system and method for plasma plating for preventing breaker failure.

### BACKGROUND OF THE INVENTION

Circuit breakers or breakers, for example, are protective devices provided to discontinue throughput in overload situations. In an exemplary implementation, breaker are employed in nuclear power generation systems to provide a safe shutdown and continued cooling of the reactor.

Breaker service includes replenishing convention lubricants at critical moving interfaces. Conventional lubricants often harden, particularly after extended stagnant periods, or where elevated temperatures exist. Hardening of conventional lubricants is believed to contribute to breaker malfunction.

Conventional lubricants promote relative motion across an interface by creating a liquid barrier that holds the surfaces apart. Conventional lubricants contain additives that promote adherence to the surface parts of the breakers to prevent the lubricant from being squeezed out of the interface. After long periods of stagnancy, the lubricant may harden and may resist motion and glue at the interface. Additionally, breakers and similar components are subject to galling, friction, wear and require periodic service to ensure adequate lubrication.

### SUMMARY OF THE INVENTION

From the foregoing it may be appreciated that a need has arisen for a system and method for plasma plating to prevent breaker failure that generates a controllable and repeatable deposition layer on a substrate. In accordance with the present invention, a system and method for plasma plating to prevent breaker failure are provided that substantially eliminate one or more of the disadvantages and problems outlined above.

According to one aspect of the present invention, a method for plasma plating a portion of a circuit breaker component to prevent circuit breaker failure is provided. The method includes positioning the circuit breaker component of a circuit breaker within a vacuum chamber and positioning a depositant in an evaporation source within the vacuum chamber. The method includes applying a dc signal to the circuit breaker component and applying a radio frequency signal to the circuit breaker component. The method further provides for heating the depositant to a temperature at or above the melting point of the depositant to generate a plasma in the vacuum chamber.

According to another aspect of the present invention, a method of manufacturing protective electronic components with plasma plating is provided. The method includes positioning a protective electronic component within a vacuum chamber and positioning a depositant within the vacuum chamber. The method includes heating the depositant to a temperature at or above the melting point of the depositant to generate a plasma in the vacuum chamber and implanting the depositant on at least a surface of the electronic component within the vacuum chamber.

According to an aspect of the present invention, a method for plasma plating components is provided to generate a deposition layer on a substrate. The method for plasma plating includes positioning a substrate within a vacuum chamber, positioning a depositant in an evaporative source within the vacuum chamber, reducing the pressure in the vacuum chamber to a level at or below 4 milliTorr, and introducing a gas into the vacuum chamber at a rate to raise the pressure in the vacuum chamber to a level at or between 0.1 milliTorr and 4 milliTorr. In other embodiments, the gas is not required to be introduced. The method also includes applying a dc signal to the substrate at a voltage amplitude at or between 1 volt to 5000 volts, applying a radio frequency signal to the substrate at a power level at or between 1 watt and 50 watts, and heating the depositant to a temperature at or above the melting point of the depositant to generate a plasma in the vacuum chamber. The plasma will preferably include both positively charged gas and depositant ions that will be attracted to the substrate, which will, preferably, be provided at a negative potential if the dc signal is provided at a negative polarity.

The present invention provides numerous technical advantages that include providing electrical components, such as but not limited to, circuit breaker components, that resist galling, friction and wear. The plasma plated surfaces provide superior lubrication, according to some aspects, and provide metallurgical contrast and engineered surface enhancement desirous for critical components.

Other technical advantages are readily apparent to one skilled in the art from the following figures, description, and claims.

### BRIEF DESCRIPTION OF THE DRAWINGS

For a more complete understanding of the present invention and the advantages thereof, reference is now made to the following brief description, taken in connection with the accompanying drawings and detailed description, wherein like reference numerals represent like parts, in which:

FIG. 1 is a schematic diagram that illustrates a system for plasma plating that can be used to plate materials, according to an embodiment of the present invention;

FIG. 2 is a top view of a vacuum chamber of a system for plasma plating that illustrates one embodiment of a platform implemented as a turntable;

FIG. 3 is a side view that illustrates the formation and dispersion of a plasma around a filament to plasma plate a substrate according to an embodiment of the present invention;

FIG. 4 is a sectional view that illustrates a deposition layer that includes a base layer, a transition layer, and a working layer;

FIG. 5 is a flowchart that illustrates a method for plasma plating according to an embodiment of the present invention;

FIG. 6 is a flowchart that illustrates a method for backsputtering using the system of the present invention, according to an embodiment of the present invention;

FIG. 7 is a schematic view of an exemplary circuit breaker;

FIG. 8 is a schematic view of the circuit breaker illustrated in FIG. 7 shown in a tripped position;

FIG. 9 is a schematic view of an exemplary circuit breaker tripping system;

FIG. 10 is a perspective view of an exemplary circuit breaker that may utilize the circuit breaker tripping system described in FIG. 9;

FIG. 11 is a perspective view of an oscillator portion of a closing spring of the circuit breaker shown in FIG. 10 illustrating surfaces that may be plasma plated according to one aspect of the present invention; and

FIG. 12 is a perspective view of a spring release latch portion of the closing spring of the circuit breaker shown in FIG. 10 illustrating surfaces that may be plasma plated according to one aspect of the present invention.

### DETAILED DESCRIPTION OF THE INVENTION

It should be understood at the outset that although an exemplary implementation of the present invention is illustrated below, the present invention may be implemented using any number of techniques, whether currently known or in existence. The present invention should in no way be limited to the exemplary implementations, drawings, and techniques illustrated below, including the exemplary design and implementation illustrated and described herein.

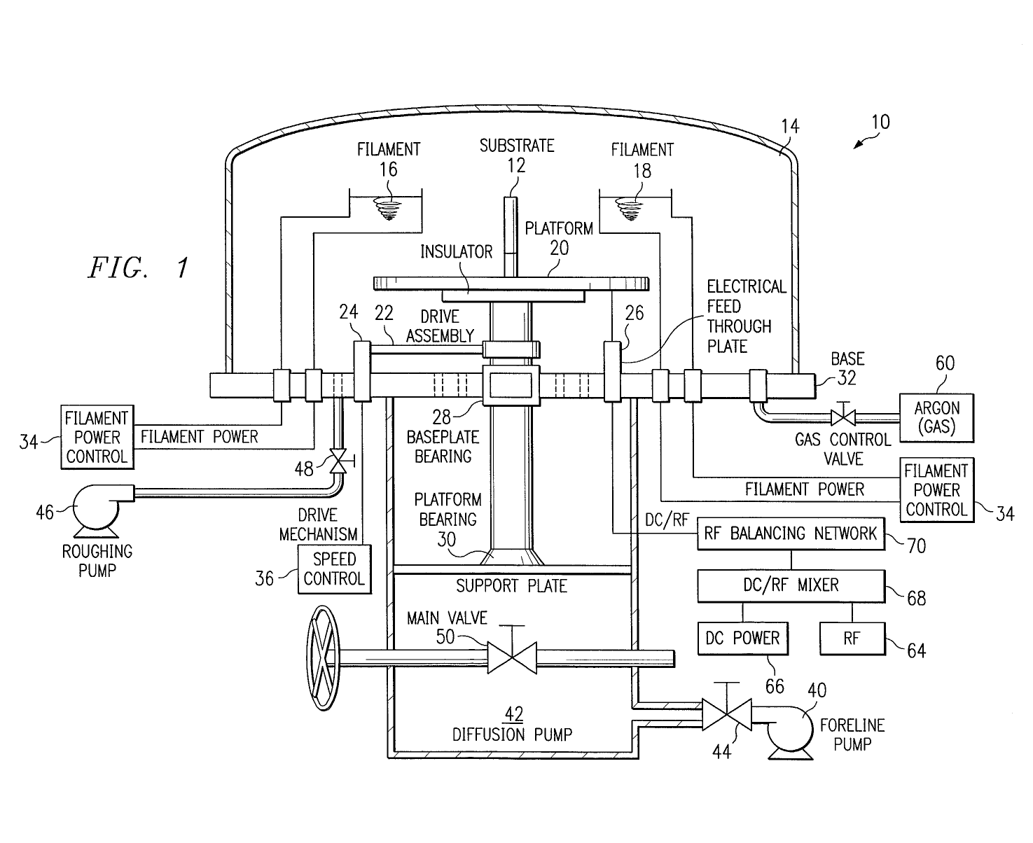

FIG. 1 is a schematic diagram that illustrates a system 10 for plasma plating that can be used to plate any of a variety of materials, according to an embodiment of the present invention. The system 10 includes various equipment used to support the plasma plating of a substrate 12 within a vacuum chamber 14. Once appropriate operating parameters and conditions are achieved, a depositant provided in a filament 16 and a filament 18 may be evaporated or vaporized to form a plasma. The plasma will contain, generally, positively charged ions from the depositant and will be attracted to the substrate 12 where they will form a deposition layer. The plasma may be thought of as a cloud of ions that surround or are located near the substrate 12. The plasma will generally develop a dark region, near the closest surface of the substrate 12 from the filament 12 and the filament 18, that provides acceleration of the positive ions into the substrate 12.

The filament 12 and the filament 14 reside within the vacuum chamber 14 along with a platform 20, which supports the substrate 12. A drive assembly 22 is shown coupled between a drive motor 24 and a main shaft of the platform 20 within the vacuum chamber 14. In the embodiment shown in FIG. 1, the platform 20 is provided as a turntable that rotates within the vacuum chamber 14. The drive assembly 22 mechanically links the rotational motion of the drive motor 24 with the main shaft of the platform 20 to impart rotation to the platform 20. The rotation of the main shaft of the platform 20 is enhanced through various support bearings such as a base plate bearing 28 and a platform bearing 30.

As is illustrated, the vacuum chamber 14 resides or is sealed on a base plate 32. The vacuum chamber 14 may be provided using virtually any material that provides the appropriate mechanical characteristics to withstand an internal vacuum and an external pressure, such as atmospheric pressure. For example, the vacuum chamber 14 may be provided as a metal chamber or as a glass bell. In an alternative embodiment, the base plate 32 serves as the platform 20 to support the substrate 12. The base plate 32 may be thought of as part of the vacuum chamber 14.

The base plate 32 also provides mechanical support for the system 10 while allowing various devices to feed through from its bottom surface to its top surface within the vacuum chamber 14. For example, the filament 16 and the filament 18 receive power from a filament power control module 34. It should be noted that although two filament power control modules 34 are shown in FIG. 1, preferably, these two modules are implemented as one module. In order to provide power to the filament 16 and the filament 18, electrical leads must feed through the base plate 32 as illustrated in FIG. 1. Similarly, the drive motor 24 must also penetrate or feed through the base plate 32 to provide mechanical action to the drive assembly 22 so that the platform 20 may be rotated. The electrical feed through 26, described more fully below, also feeds through the base plate 32 and provides an electrical conductive path between the platform 20 and various signal generators, also described more fully below. In a preferred embodiment, the electrical feed through 26 is provided as a commutator that contacts the bottom surface of the platform 20, in the embodiment where the platform 20 is implemented as a turntable. The electrical feed through 26 may be implemented as a commutator and may be implemented as a metal brush which can contact the bottom surface of the platform 20 and maintain an electrical contact even if the platform 20 rotates.

The filament power control module 34 provides an electric current to the filament 16 and the filament 18. In one embodiment, the filament power control module 34 can provide current to the filament 16 for a particular duration, and then provide current to the filament 18 during a second duration. Depending upon how the filaments are configured, the filament power control module 34 may provide current to both the filament 16 and the filament 18 at the same time or during separate intervals. This flexibility allows more than one particular depositant material to be plasma plated onto the substrate 12 at different times. The filament power control module 34 preferably provides alternating current to the filaments, but may provide a current using any known method of generating current. In a preferred embodiment, the filament power control module 34 provides current at an amplitude or magnitude that is sufficient to generate enough heat in the filament 16 to evaporate or vaporize the depositant.

In order to ensure even heating of the depositant, which will be provided at or in the filament 16 or the filament 18, the current provided by the filament control module 34 will preferably be provided using incremental staging so that a more even heat distribution will occur in the depositant that is being melted within the vacuum chamber 14.

In a preferred embodiment, the platform 20 is implemented as a turntable and rotates using the mechanical linkage as described above. A speed control module 36, as shown in FIG. 1, may be provided to control the speed of the rotation of the platform 20. Preferably, the rotation of the platform 20 occurs at a rate from five revolutions per minutes to 30 revolutions per minute. It is believed that an optimal rotational rate of the platform 20 for plasma plating is provided at a rotational rate of 12 revolutions per minute to 15 revolutions per minute. The advantages of rotating the platform 20 are that the substrate 12 can be more evenly plated or coated. This is especially true when multiple substrates are provided on the surface of the platform 20. This allows each one of the multiple substrates to be similarly positioned, on average, within the vacuum chamber 14 during the plasma plating process.

In other embodiments, the platform 20 may be provided at virtually any desired angle or inclination. For example, the platform 20 may be provided as a flat surface, a horizontal surface, a vertical surface, an inclined surface, a curved surface, a curvilinear surface, a helical surface, or as part of the vacuum chamber such as a support structure provided within the vacuum chamber. As mentioned previously, the platform 20 may be stationary or rotate. In an alternative embodiment, the platform 20 includes rollers that may be used to rotate one or more substrates.

The platform 20, in a preferred embodiment, provides or includes an electrically conductive path to provide a path between the electrical feed through 26 and the substrate 12. In one embodiment, platform 20 is provided as a metal or electrically conductive material such that an electrically conductive path is provided at any location on the platform 20 between the electrical feed through 26 and the substrate 12. In such as a case, an insulator 21, will be positioned between the platform 20 and the shaft that rotates the platform 20 to provide electrical isolation. In another embodiment, the platform 20 includes electrically conductive material at certain locations on its top surface that electrically coupled to certain locations on the bottom surface. In this manner, the substrate 12 can be placed at an appropriate location on the top side of the platform 20 while the electrical feed through 26 may be positioned or placed at an appropriate location on the bottom side of the platform 20. In this manner, the substrate 12 is electrically coupled to the electrical feed through 26.

The electrical feed through 26 provides a dc signal and a radio frequency signal to the platform 20 and the substrate 12. The desired operational parameters associated with each of these signals are described more fully below. Preferably, the dc signal is generated by a dc power supply 66 at a negative voltage and the radio frequency signal is generated by an rf transmitter 64 at a desired power level. The two signals are then preferably mixed at a dc/rf mixer 68 and provided to the electrical feed through 26 through an rf balancing network 70, which provides signal balancing by minimizing the standing wave reflected power. The rf balancing network 70 is preferably controlled through a manual control.

In an alternative embodiment, the platform 20 is eliminated, including all of the supporting hardware, structures, and equipment, such as, for example, the drive motor 24, and the drive assembly 22. In such a case the substrate 12 is electrically coupled to the electrical feed through 26.

The remaining equipment and components of the system 10 of FIG. 1 are used to create, maintain, and control the desired vacuum condition within the vacuum chamber 14. This is achieved through the use of a vacuum system. The vacuum system includes a roughing pump 46 and a roughing valve 48 that is used to initially pull down the pressure in the vacuum chamber 14. The vacuum system also includes a foreline pump 40, a foreline valve 44, a diffusion pump 42, and a main valve 50. The foreline valve 44 is opened so that the foreline pump 40 can began to function. After the diffusion pump 42 is warmed or heated to an appropriate level, the main valve 50 is opened, after the roughing pump 40 has been shut in by closing the roughing valve 44. This allows the diffusion pump 42 to further reduce the pressure in the vacuum chamber 14 below a desired level.

A gas 60, such as argon, may then be introduced into the vacuum chamber 14 at a desired rate to raise the pressure in the vacuum chamber 14 to a desired pressure or to within a range of pressures. A gas control valve controls the rate of the flow of the gas 60 into the vacuum chamber 14 through the base plate 32.

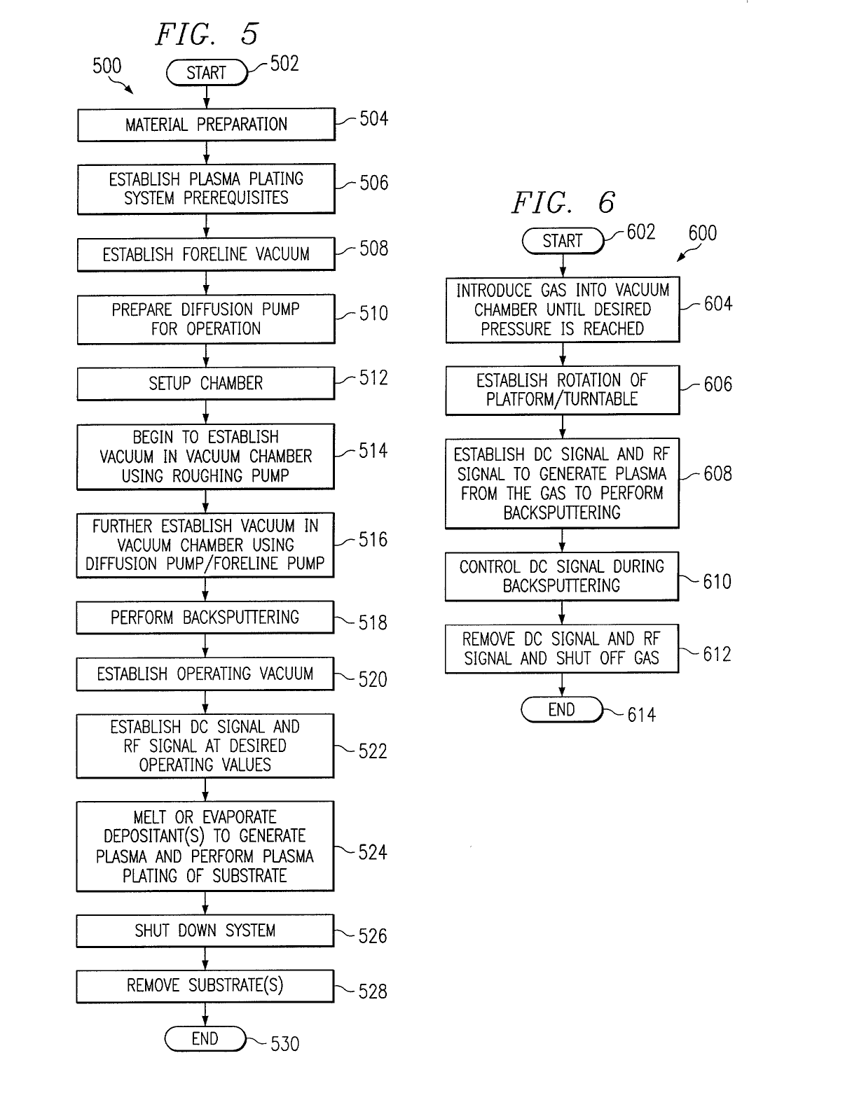

Once all of the operating parameters and conditions are established, as will be described more fully below in connection with FIGS. 5 and 6 according to the teachings of the present invention, plasma plating occurs in system 10. The substrate 12 may be plasma plated with a deposited layer, which may include one or more layers such as a base layer, a transitional layer, and a working layer, through the formation of a plasma within the vacuum chamber 14. The plasma will preferably include positively charged depositant ions from the evaporated or vaporized depositant along with positively charged ions from the gas 60 that has been introduced within the vacuum chamber 14. It is believed, that the presence of the gas ions, such as argon ions, within the plasma and ultimately as part of the depositant layer, will not significantly or substantially degrade the properties of the depositant layer. The introduction of the gas into the vacuum chamber 14 is also useful in controlling the desired pressure within the vacuum chamber 14 so that a plasma may be generated according to the teachings of the present invention. In an alternative embodiment, the plasma plating process is achieved in a gasless environment such that the pressure within the vacuum chamber 14 is created and sufficiently maintained through a vacuum system.

The generation of the plasma within the vacuum chamber 14 is believed to be the result of various contributing factors such as thermionic effect from the heating of the depositant within the filaments, such as the filament 16 and the filament 18, and the application of the dc signal and the radio frequency signal at desired voltage and power levels, respectively.

The vacuum system of the system 10 may include any of a variety of vacuum systems such as a diffusion pump, a foreline pump, a roughing pump, a cryro pump, a turbo pump, and any other pump operable or capable of achieving pressures within the vacuum chamber 14 according to the teachings of the present invention.

As described above, the vacuum system includes the roughing pump 46 and the diffusion pump 42, which is used with the foreline pump 40. The roughing pump 46 couples to the vacuum chamber 14 through the roughing valve 48. When the roughing valve 48 is open, the roughing pump 46 may be used to initially reduce the pressure within the vacuum chamber 14. Once a desired lower pressure is achieved within the vacuum chamber 14, the roughing valve 48 is closed. The roughing pump 46 couples to the vacuum chamber 14 through a hole or opening through the base plate 32. The roughing pump 46 will preferably be provided as a mechanical pump. In a preferred embodiment of the vacuum system of the system 10 as shown in FIG. 1. The vacuum system in this embodiment includes a foreline pump coupled to a diffusion pump 42 through a foreline valve 44. The foreline pump 40 may be implemented as a mechanical pump that is used in combination with the diffusion pump 42 to reduce the pressure within the vacuum chamber 14 to a level even lower than that which was produced through the use of the roughing pump 46.

After the roughing pump has reduced the pressure within the vacuum chamber 14, the diffusion pump 42, which uses heaters and may require the use of cooling water or some other substance to cool the diffusion pump 42, couples with the vacuum chamber 14 through a main valve 50 and through various holes or openings through the base plate 32 as indicated in FIG. 1 by the dashed lines above the main valve 50 and below the platform 20. Once the diffusion pump 42 has been heated up and made ready for operation, the main valve 50 may be opened so that the pressure within the vacuum chamber 14 may be further reduced through the action of the diffusion pump 42 in combination with the foreline pump 44. For example, the pressure within the vacuum chamber 14 may be brought below 4 milliTorr. During a backsputtering process, the pressure in the vacuum chamber 14 may be dropped to a level at or below 100 milliTorr on down to 20 milliTorr. Preferably, the pressure within the vacuum chamber 14 during a backsputtering process will be at a level at or below 50 milliTorr on down to 30 milliTorr. During normal operation of the system 10 during a plasma plating process, the pressure within the vacuum chamber 14 may be reduced by the vacuum system to a level at or below 4 milliTorr on down to a value of 0.1 milliTorr. Preferably, the vacuum system will be used during a plasma plating process to reduce the pressure within the vacuum chamber 14 to a level at or below 1.5 milliTorr on down to 0.5 milliTorr.

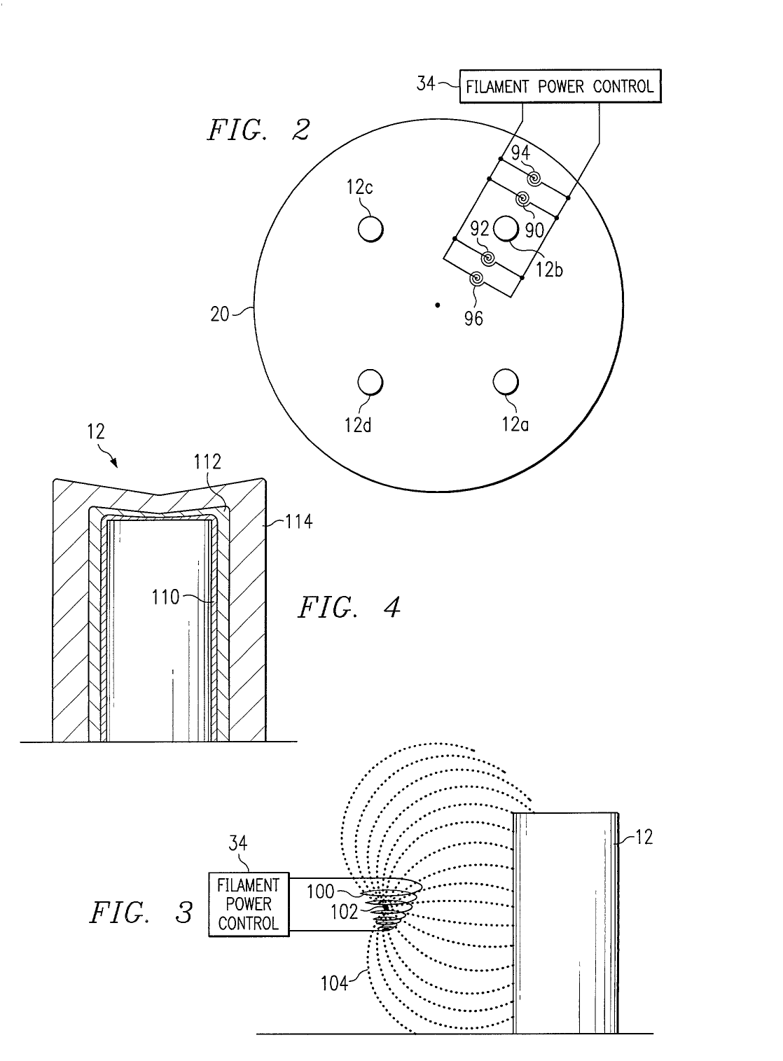

FIG. 2 is a top view of a vacuum chamber of a system for plasma plating that illustrates one embodiment of a platform implemented as a turntable 20. The turntable 20 is shown with substrates 12a, 12b, 12c, and 12d positioned, symmetrically on the surface of the turntable 20. The turntable 20 may rotate either clockwise or counterclockwise. The substrates 12a-12d may be virtually any available material and are shown in FIG. 2 as round, cylindrical components such that the top view of each of the substrates presents a circular form.

The filament power control module 34 is electrically coupled to a first set of filaments 94 and 96 and a second set of filaments 90 and 92. Although the electrical connections are not fully illustrated in FIG. 2, it should be understood that the filament power control module 34 may supply current to the first set of filaments 94 and 96 or to the second set of filaments 90 and 92. In this manner, the deposition layer may be provided with two sublayers such as a base layer and a working layer. The base layer will preferably be applied first through depositants provided in the first set of filaments 94 and 96 while the working layer will be deposited on the base layer of the substrates 12a-12d using the depositants provided at the second set of filaments 90 and 92.

The arrangement of the substrates in FIG. 2 may be described as an array of substrates that include inwardly facing surfaces, which are closer to the center of the turntable 20, and outwardly facing surfaces, which are closer to the outer edge of the turntable 20. For example, the inwardly facing surfaces of the array of substrates 12a-d will be presented to the filament 92 and the filament 96, at different times of course, as they are rotated near the filaments. Similarly, the outwardly facing surfaces of the substrates 12a-d will be presented to the filaments 90 and 94 as they rotate near these filaments.

As mentioned previously, the filament power control module 34 may provide a current in virtually any form, such as a direct current or an alternating current, but preferably provides current as an alternating current.

In operation, turntable 20 rotates, for example, in a clockwise direction such that after substrate 12b passes near or through the filaments, the next substrate that will pass near or through the filaments is substrate 12c, and so on. In one example, the first set of filaments 94 and 96 are loaded with a depositant, such as nickel (or titanium), and the second set of filaments are loaded with a depositant such as the metal alloy silver\palladium. This example illustrates a two shot application or a two layer deposition layer.

After all of the operating parameters have been established within the vacuum chamber, as described throughout herein, the filament power control module 34 may energize or provide alternating current to the first set of filaments 94 and 96 so that the nickel will evaporate or vaporize to form a plasma with the gas, such as argon gas, within the vacuum chamber. The positively charged nickel ions and the positively charged argon ions in the plasma will be attracted to the substrates 12a-d, which are at a negative potential. Generally, the closer the substrate is to the first set of filaments 90 and 92 as it rotates, the more material will be deposited. Because the turntable is rotating, a uniform or more even layer will be applied to the various substrates.

After the first plasma has been plated onto the array of substrates 12a-d to form a base layer of the depositant layer on the substrates, the filament power control module 34 is energized so that a sufficient amount of current is provided to the second set of filaments 90 and 92. Similarly, a plasma is formed between the argon ions and the silver\palladium ions and the working layer is then formed to the substrates that are being rotated.

During the first shot when the base layer is being applied, the outwardly facing surfaces of substrates 12a-d are primarily coated through the nickel depositant located in the filament 94. Similarly, the inwardly facing surfaces of the substrates are coated by the nickel depositant located in the filament 96. The same relation holds true for the second shot where the silver\palladium is plasma plated onto the substrates to form the deposit layer.

FIG. 3 is a side view that illustrates the formation and dispersion of a plasma around a filament 100 to plasma plate a substrate 12 according to an embodiment of the present invention. The filament 100 is implemented as a wire basket, such as tungsten wire basket, and is shown with a depositant 102 located, and mechanically supported, within the filament 100. As the filament power control module 34 provides sufficient current to the filament 100, the depositant 102 melts or vaporizes and a plasma 104 is formed. Of course, all of the operating parameters of the present invention must be present in order to achieve the plasma state so that plasma plating may takes place.

The substrate 12, which is provided at a negative potential, attracts the positive ions of the plasma 104 to form a deposition layer. As is illustrated, the dispersion pattern of the plasma 104 results in most of the positive ions of the plasma 104 being attracted to the side adjacent or nearest to the filament 100 and the depositant 102. Some wrap around will occur such as that illustrated by the plasma 104 contacting the top surface of the substrate 12. Similarly, some of the positive ions of the plasma 104 may be attracted to the platform or turntable. As is illustrated, the present invention provides an efficient solution for the creation of a deposition layer by ensuring that most of the ions from the depositant are used in the formation of the deposition layer.

FIG. 4 is a sectional view that illustrates a deposition layer of the substrate 12 that includes a base layer 110, a transition layer 112, and a working layer 114. It should be noted at the outset that the thickness of the various layers that form the deposition layer are grossly out of proportion with the size of the substrate 12; however, the relative thicknesses of the various sublayers or layers of the deposition layer are proportionate to one another, according to one embodiment of the present invention.

Generally, the thickness of the entire deposition layer on the substrate, according to the teachings of the present invention, are believed to generally range between 500 and 20,000 Angstroms. In a preferred embodiment, the entire thickness of the deposition layer is believed to range between 3,000 and 10,000 Angstroms. The present invention provides excellent repeatability and controllability of deposition layer thicknesses, including all of the sublayers such as the base layer 110, the transition layer 112, and the working layer 114. It is believed that the present invention can provide a controllable layer thickness at an acuracy of around 500 Angstroms. It should also be mentioned that the present invention may be used to form a deposition layer with one or any multiple of sublayers.

The thickness of the deposition layer is normally determined based on the nature of intended use of the plasma plated substrate. This may include such variables as the temperature, pressure, and humidity of the operating environment, among many other variables and factors. The selection of the desired metal or depositant type for each layer is also highly dependent upon the nature of the intended use of the plasma plated substrate.

For example, the present invention prevents or substantially reduces galling or mating or interlocking components. Galling includes the seizure of mated components that often occur when two surfaces, such as threaded surfaces, are loaded together. Galling can cause components to fracture and break, which often results in severe damage. Plasma plating may be used to prevent or reduce galling by plating one or more contacting surfaces. Various depositants may be used to achieve this beneficial effect. It is believed, however, that galling is preferably reduced through a plasma plating process that deposits a base layer of nickel or titanium and a working layer of a silver/palladium metal alloy on one or more contacting surfaces. For high temperature applications, such as over 650 degrees Fahrenheit, it is believed that the galling is preferably reduced through a plasma plating process that deposits a nickel or titanium base layer and a working layer of gold.

It has been found through experimentation that chromium does not work well to reduce galling, this includes when the chromium is deposited as either the base layer, the transition layer, or the working layer. It is believed that chromium may be a depositant that is more difficult to control during the plasma plating process.

Plasma plating may also be used to plate valve parts, such as valve stems in nonnuclear applications, and are preferably plasma plated using a titanium base layer, a gold transition layer, and an indium working layer. In nuclear applications, such as nuclear power plant applications, indium is not a preferred plasma plating depositant because it is considered to be too much of a radioactive isotope absorber. Instead, valve stems in nuclear applications are preferably plasma plated using a nickel base layer and a silver/palladium metal alloy working layer.

As is illustrated in FIG. 4, the working layer 14 is normally provided at a substantially larger thickness than the corresponding transition layer 112 and the base layer 110. It should also be noted that the coating of the top of the substrate 12 is shown to be thin at or near the center or middle of the substrate 12. This effect is due to how the filaments are positioned during the plasma plating process. For example, if the filaments are positioned similarly to that illustrated in FIGS. 2-3, the middle or center portion of the substrate 12 will generally have a thinner overall profile than the side of the deposition layer.

Although various ranges of thicknesses have been discussed herein, it should be understood that the present invention is not limited to any maximum deposition layer thickness. The thickness of the deposition layer, especially the thickness of the working layer 114, can be provided at virtually any desired thickness, normally depending upon the operating environment in which the plasma plated substrate 12 will be introduced. The base layer 110 and the transition layer 112 and any other layers below the working layer 114 will preferably be provided at a substantially smaller thickness than the corresponding thickness of the working layer 114. For example, the base layer 110 and the transition layer 112 may be provided at a thickness ranging from 500 to 750 Angstroms while the working layer 114 may be provided at virtually any thickness such as for example 18,000 Angstroms.

FIG. 5 is a flow chart of a method 500 for plasma plating according to an embodiment of the present invention. The method 500 begins at block 502 and proceeds to block 504. At block 504, the material or substrate that will be plasma plated is prepared for the process. This may include cleaning the substrate to remove any foreign materials, contaminants, and oils. Any of a variety of known cleaning processes may be used such as those defined by the Steel Structures Painting Council (SSPC). For example, the SSPC-5 standard may be employed to ensure that a substrate is cleaned to a white metal condition. Similarly, the SSPC-10 standard may be employed. Preferably, the substrate will undergo an abrasive blasting, such as for example, bead blasting to further ensure that any foreign materials or contaminants are removed. It should be noted that an oxidation layer may be present on the surface of the substrate. The present invention allows for a deposition layer to be plasma plated onto the substrate surface, even in the presence of an oxidation layer, with excellent adhesion and mechanical properties.

The method 500 proceeds next to block 506 where the plasma plating system prerequisites are established. Depending upon the implementation of the system for plasma plating, this may involve any of a variety of items. In the situation where a diffusion pump is used as part of the vacuum system, items such as the availability of cooling water must be established. Similarly, the adequate availability of lube oil and air to operate the various equipment, valves, and machinery associated with the system for plasma plating must be established. An adequate supply of gas, such as argon gas, should also be verified and checked at this point before proceeding to block 510.

At block 510, assuming that a diffusion pump is used as part of the vacuum system, the diffusion pump is prepared for operation. This may include opening a foreline valve and the starting of the foreline vacuum pump which is used in combination with the diffusion pump. Once a foreline vacuum has been drawn, the heaters of the diffusion pump may be energized. This places the diffusion pump in service.

The method 500 proceeds next to block 512 where the vacuum chamber is set up. This includes any number of processes such as positioning the substrate within the vacuum chamber. This is normally achieved by positioning or placing the substrate at a specified location on a platform or turntable located within the vacuum chamber. Before accessing the internal volume of the vacuum chamber, the vacuum chamber seal must be broken and the bell jar or outer member is preferably lifted away from its base plate. Once the substrate is positioned on the platform, the filaments may be positioned relative to the placement of the substrate.

The positioning of the filaments may involve any number of techniques and includes such variables as the amount and type of depositant to be provided at the filament, and the distance, not only relative to the substrate, but relative to other filaments. Generally, the filament will be located a distance ranging from 0.1 inches to 6 inches from the substrate, as measured from the center line of the filament, or from the depositant, to the closest point of the substrate. Preferably, however, the distance between the filament or the depositant and the substrate will range anywhere from 2.75 inches to 3.25 inches when the depositant will serve as the base layer or transition layer of the deposition layer. Similarly, when the depositant will serve as the working layer of the deposition layer that will be deposited on the substrate, the distance between the filament or the depositant and the substrate is preferably provided at a distance between 2 inches and 2.5 inches.

In the situation where multiple depositants or multiple shots will be performed in the plasma plating process, it is necessary to consider the placement of the filaments that will hold the first depositant relative to those that will hold the second depositant as well as each of the filament's position relative to each other and the substrate. Generally the distance of a second filament from a first filament, which will include a depositant that will serve as a base layer, transition layer, or a working layer of a deposition layer, should be anywhere between 0.1 inches and 6 inches.

The spacing between filaments that include depositants that will serve as a base layer, is generally provided between 0.1 inches and 6 inches. Preferably, this distance shall be between 3 inches and 4 inches. The foregoing filament spacing information also applies when the depositant provided in the filaments will serve as the transition layer in the deposition layer. Similarly, the spacing between filaments, which include a depositant that will serve as the working layer of the deposition layer, should generally be between 0.1 inches and 6 inches, but, preferably, will be between 2.5 inches and 3 inches.

The chamber setup of block 512 may also need to take into account the arrangement of an array of substrates on the platform that are being plasma plated. For example, a filament that is positioned in the vacuum chamber so that it will provide a dispersion pattern to provide depositant coverage to inwardly facing surfaces of an array of substrates, it may require anywhere from 20 to 80 percent less mass or weight of depositant when compared with a filament positioned in the vacuum chamber to provide coverage for the array of outwardly facing surfaces. The reference to inwardly and outwardly are relative to the platform or turntable with inwardly referring to those surfaces closer to the center of the platform or turntable. This is because the efficiency of the plasma plating process is greater for the inwardly facing surfaces of an array of substrates than at the outwardly facing surfaces of the array of substrates because of the forces attracting the, generally, positive ions of the plasma. This also ensures that the thickness of the deposition layer on the inwardly facing surfaces and the outwardly facing surfaces are more uniform. In such a case, the weight or mass of the depositant will, preferably, need to vary between such filament positions. Generally, the variance in mass or weight between the two locations may be anywhere from 20 to 80 percent different. Preferably, the depositants in the filaments covering the inwardly facing surfaces will use 40 to 50 percent less mass or weight than the depositants of the filaments covering the outwardly facing surfaces. The amount of the depositant placed in the filaments corresponds to the desired thickness of the deposition layer, and any sublayers thereof. This was discussed more fully and is illustrated more fully in connection with FIG. 3.

The type of filament affects the dispersion pattern achieved through the melting or evaporation of its depositant during the creation of the plasma. Any of a variety of filament types, shapes, and configurations may be used in the present invention. For example, the filament may be provided as a tungsten basket, a boat, a coil, a crucible, a ray gun, an electron beam gun, a heat gun, or as any other structure, such as a support structure provided within the vacuum chamber. The filaments are generally heated through the application of an electric current through the filament. However, any method or means of heating the depositant within the filament may be used in the present invention.

The setup of the vacuum chamber also includes placing the depositants in the one or more filaments. The present invention contemplates the use of virtually any material that is capable of being evaporated under the conditions and parameters of the present invention so that a plasma will form. For example, the depositant may include virtually any metal, such as a metal alloy, gold, titanium, chromium, nickel, silver, tin, indium, lead, copper, palladium, silver/palladium and any of a variety of others. Similarly, the depositant may include any other materials such as carbon, nonmetals, ceramics, metal carbides, metal nitrates, and any of a variety of other materials. The depositants will generally be provided in a pellet, granule, particle, powder, wire, ribbon, or strip form. Once the filaments have been properly positioned and loaded, the vacuum chamber may be closed and sealed. This may include sealing the bell portion of the vacuum chamber with its base plate.

The method 500 proceeds next to block 514 where preparations are made to begin establishing a vacuum condition within the vacuum chamber. In one embodiment, such as the system 10 shown in FIG. 1, a roughing pump is started to begin evacuating the vacuum chamber and to bring the pressure down within the vacuum chamber to a sufficient level so that additional pumps may take over to further reduce the pressure within the vacuum chamber. In one embodiment, the roughing vacuum pump is a mechanical pump that may be started, and a roughing valve may then be opened to provide access to the vacuum chamber. Once the roughing vacuum pump has achieved its desired function and has reduced the pressure in the vacuum chamber to its desired or designed level, the roughing valve is shut. At this point, the method 500 transitions to block 516.

At block 516, the pressure within the vacuum chamber is further reduced using another vacuum pump. For example, in one embodiment, a diffusion pump/foreline pump is utilized to further reduce the pressure within the vacuum chamber. In the embodiment of the present invention as illustrated in FIG. 1, this is achieved by opening the main valve and allowing the diffusion pump, supported by the mechanical foreline pump, to further pull or reduce the pressure in the vacuum chamber.

Generally, the pressure in the vacuum chamber is reduced to a level that is at or below 4 milliTorr. Preferably, the pressure in the vacuum chamber is reduced to a level that is at or below 1.5 milliTorr. In the event that backsputtering, which is described below in connection with block 518 of the method 500, is to be performed, the pressure in the vacuum chamber is reduced to a level below 100 milliTorr and generally in a range between 20 milliTorr and 100 milliTorr. In a preferred embodiment when backsputtering is to be performed, the pressure is reduced in the vacuum chamber at a level below 50 milliTorr, and generally at a level between 20 milliTorr and 50 milliTorr.

Preceding next to block 518, a backsputtering process may be performed to further clean and prepare the substrate. It should be understood, however, that such a process is not mandatory. The backsputtering process is described in more detail below in connection with FIG. 6. The backsputtering process may include the rotation of the platform or turntable within the vacuum chamber. In such a case, the turntable will generally be rotated at a rate at or between 5 revolutions per minute and 30 revolutions per minute. Preferably, the turntable will be rotated at a rate between 12 revolutions per minute and 15 revolutions per minute. The operation of the turntable, which also will preferably be used as the deposition layer is being formed on the substrate according to the teachings of the present invention.

Method 500 proceeds next to block 520 where an operating vacuum is established. Although a vacuum condition has already been established within the vacuum chamber, as previously discussed in connection with block 514 and 516, an operating vacuum can now be established through the introduction of a gas into the vacuum chamber at a flow rate that will raise the pressure in the vacuum chamber to a level generally at or between 0.1 milliTorr and 4 milliTorr. Preferably, the introduction of the gas is used to raise the pressure in the vacuum chamber to a level that is at or between 0.5 milliTorr and 1.5 milliTorr. This will ensure that there are no depositant ion collisions within the plasma, which will increase the depositant efficiency and provide a clean, highly adhered deposition layer to the substrate. The gas that is introduced into the vacuum chamber may be any of a variety of gases but will preferably be provided as an inert gas, a noble gas, a reactive gas or a gas such as argon, xenon, radon, helium, neon, krypton, oxygen, nitrogen, and a variety of other gases. It is desirable that the gas is a noncombustible gas. It should be understood that the present invention does not require the introduction of a gas but may be performed in the absence of a gas.

At block 522, various operating parameters and values of the system are established. This will generally include the rotation of a turntable, if desired, the application of a dc signal, and the application of a radio frequency signal. Assuming that the platform includes a turntable or some other rotating device, the turntable rotation will preferably be established at this point. This assumes, of course, that the rotation of the turntable was not previously started and the discretionary backsputtering block 518. Once the rotation of the turntable has been established, the dc signal and the rf signal may be applied to the substrate. The application of the dc signal to the substrate will generally be provided at a voltage amplitude that is at or between one volt and 5,000 volts. Note that the polarity of the voltage will preferably be negative; however, this is not always required. In a preferred embodiment, the application of the dc signal to the substrate will be provided at a voltage level at or between negative 500 volts and negative 750 volts.

The application of the radio frequency signal to the substrate will generally be provided at a power level that is at or between 1 watt and 50 watts. Preferably, the power level of the radio frequency signal will be provided at 10 watts or between a range defined by 5 watts and 15 watts. The frequency of the radio frequency signal will generally be provided at an industrial specified frequency value in either the kilohertz range or the megahertz range. Preferably, the frequency signal will be provided at a frequency of 13.56 kilohertz. Although the term radio frequency has been used throughout to describe the generation and application of the radio frequency signal to the substrate, it should be understood that the term radio frequency should not be limited to its commonly understood definition of signals having frequencies roughly between 10 kilohertz and 100,000 megahertz. The term radio frequency shall also include any signal with a frequency component that is operable or capable of assisting with the creation or excitation of a plasma in a vacuum chamber.

Block 522 will also preferably include the mixing of the dc signal and the radio frequency signal, using mixer circuitry, to generate a mixed signal. This allows only one signal to be applied to the substrate. This is generally achieved using the electrical feed through that extends through the base plate of the vacuum chamber and contacts an electrically conductive portion of the platform, which in turn electrically couples to the substrate or substrates. Block 522 may also include the balancing of the mixed signal through the use of a radio frequency balancing network. Preferably, the mixed signal is balanced by minimizing the standing wave reflected power. This is preferably controlled through a manual control.

As the output or load characteristics of the antenna or output changes, as seen from the mixer circuitry, problems can arise when electrical signals or waves are reflected from the output load back to the mixer or source. These problems may include damage to the radio frequency transmitter and a reduction in the transfer of power to the substrate and vacuum chamber to ensure the formation of a sufficient plasma to achieve a successful plasma plating process.

This problem can be reduced or solved by including the radio frequency balancing network that can adjust its impedance, including in one embodiment its resistance, inductance, and capacitance, to match or reduce the presence of reflected waves. The impedance and electrical characteristics of the output load or antenna are affected by such things as the presence and/or absence of a plasma and the shape and properties of the substrate or substrates on the platform. Because of such changes during the plasma plating process, the radio frequency balancing network may need to be adjusted during the process to minimize the standing wave reflected power or, stated differently, to prevent or reduce the standing wave ratio return to the radio frequency transmitter. Preferably, these adjustments are performed manually by an operator during the plasma plating process. In other embodiments, the radio frequency balancing network is automatically adjusted. Care must be taken, however, to ensure that the automatic adjustment does not over compensate or poorly track the changes in the output load.

The method 500 proceeds next to block 524 where the depositant or depositants are melted or evaporated so that a plasma will be generated. The generation of the plasma at the conditions provided by the present invention will result in a deposition layer being formed on the surface of the substrate through plasma plating. It is believed that the deposition layer is formed at a medium energy level on the average of between 10 eV and 90 eV.

The depositants are generally evaporated or vaporized by providing a current through the filament around the depositant. In a preferred embodiment, the depositants are slowly or incrementally heated to achieve a more even heat distribution in the depositant. This also improves the formation of the plasma. The current may be provided as an alternating current or as any other current that is sufficient to generate heat in the filament that will melt the depositant. In other embodiments, the depositant may be heated through the introduction of an agent that is in chemical contact with the depositant. In still other embodiments, the depositant may be heated through the use of electromagnetic or microwave energy.

The conditions in the vacuum chamber will be correct for the formation of a plasma. The plasma will generally include gas ions, such as argon ions, and depositant ions, such as gold, nickel, or palladium ions. The gas ions and the depositant ions will generally be provided as positive ions due to the absence of one or more electrons. The creation of the plasma is believed to be assisted through the introduction of the radio frequency signal and because of thermionic phenomena due to the heating of the depositants. It is contemplated that in some situations, a plasma may be generated that includes negatively charged ions.

The negative potential established at the substrate due to the dc signal will attract the positive ions of the plasma. Once again, this will primarily include depositant ions and may include gas ions, such as argon gas ions from the gas that was introduced earlier in method 500. The inclusion of the gas ions, such as argon ions, are not believed to degrade the material or mechanical characteristics of the deposition layer.

It should be noted that some prior literature has suggested that the introduction of a magnet at or near the substrate is desirable to influence the path of the ions of the plasma as they are attracted to the substrate to form the deposition layer. Experimental evidence now suggests that the introduction of such a magnet is actually undesirable and produced unwanted effects. The presence of the magnet may lead to uneven deposition thicknesses, and prevent or significantly impede the controllability, repeatability, and reliability of the process.

Whenever the deposition layer is designed to include multiple sublayers, multiple shots must be performed at block 524. This means that once the base layer depositants have been melted through the heating of their filaments, the transition layer depositants (or the depositant of the next layer to be applied) are heated and melted by the introduction of heat at their filaments. In this manner, any number of sublayers may be added to the deposition layer. Before successive depositant sublayers are formed, the preceding layer shall have been fully or almost fully formed. The method 500 thus provides the significant advantage of allowing a deposition layer to be created through multiple sublayers without having to break vacuum and reestablish vacuum in the vacuum chamber. This can significantly cut overall plasma plating time and costs.

The method 500 proceeds next to block 526 where the process or system is shut down. In the embodiment of the system shown in FIG. 1, the main valve is closed and a vent valve to the vacuum chamber is opened to equalize pressure inside the vacuum chamber. The vacuum chamber may then be opened and the substrate items may be immediately removed. This is because the method 500 does not generate excessive heat in the substrates during the plasma plating process. This provides significant advantages because the material or mechanical structure of the substrate and deposition layer are not adversely affected by excessive temperature. The plasma plated substrates may then be used as needed. Because the temperature of the substrates are generally at a temperature at or below 125 Fahrenheit, the substrates can generally be immediately handled without any thermal protection.

The method 500 provides the additional benefit of not generating any waste byproducts and is environmentally safe. Further, the method 500 is an efficient process that efficiently uses the depositants such that expensive or precious metals, such as gold and silver, are efficiently utilized and are not wasted. Further, due to the fact that the present invention does not use high energy deposition techniques, no adverse metallurgical or mechanical effects are done to the substrate. This is believed to be due to the fact that the deposition layer of the present invention is not deeply embedded within the substrate, but excellent adherence, mechanical, and material properties are still exhibited by the deposition layer. After the substrates have been removed at block 528, the method 500 ends at block 530.

FIG. 6 is a flow chart of a method 600 for backsputtering using the system and method of the present invention, according to an embodiment of the present invention. As mentioned previously, backsputtering may be used to further clean the substrate before a deposition layer is formed on the substrate through plasma plating. Backsputtering generally removes contaminants and foreign materials. This results in a cleaner substrate which results in a stronger and more uniform deposition layer. The method 600 begins at block 602 and proceeds to block 604 where a gas is introduced into the vacuum chamber at a rate that maintains or produces a desired pressure within the vacuum chamber. This is similar to what was previously described in block 520 in connection with FIG. 5. Generally, the pressure in the vacuum chamber should be at a level at or below 100 milliTorr, such as at a range between 20 milliTorr and 100 milliTorr. Preferably, the pressure is provided at a level at or between 30 milliTorr and 50 milliTorr.

The method 600 proceeds next to block 606 where rotation of the platform or turntable is established, if applicable. As mentioned previously, the rotation of the turntable may be provided at a rate between 5 revolutions per minute and 30 revolutions per minute but is preferably provided at a rate between 12 revolutions per minute and 15 revolutions per minute.

Proceeding next to block 608, a dc signal is established and is applied to the substrate. The dc signal will generally be provided at an amplitude at or between one volt and 4,000 volts. Preferably, the dc signal will be provided at a voltage between negative 100 volts and negative 250 volts.

Block 608 also involves the generation of a radio frequency signal that will be applied to the substrate. The radio frequency signal will generally be provided at a power level at or between 1 watt and 50 watts. Preferably, the radio frequency signal will be provided at a power level of 10 watts or at or between 5 and 15 watts. The dc signal and the radio frequency signal are preferably mixed, balanced, and applied to the substrate as a mixed signal. As a consequence, a plasma will form from the gas that was introduced at block 604. This gas will generally be an inert gas or noble gas such as argon. The formation of the plasma includes positive ions from the gas. These positive ions of the plasma will be attracted and accelerated to the substrate, which will preferably be provided at a negative potential. This results in contaminants being scrubbed or removed from the substrate. Once the contaminants or foreign matter are removed from the substrate, they are sucked out of the vacuum chamber through the operation of the vacuum pump, such as the diffusion pump.

Proceeding next to block 610, the backsputtering process continues for a period of time that is generally between 30 seconds and one minute. Depending on the condition and cleanliness of the substrate, the backsputtering process may continue for more or less time. Generally, the backsputtering process is allowed to continue until the capacitance discharge, created by the backsputtering process is substantially complete or is significantly reduced. This may be visually monitored through the observation of sparks or light bursts that coincide with the capacitive discharge from the contaminants from the substrate. This may be referred to as microarcing.

During the backsputtering process, the dc signal must be controlled. This is normally achieved through manual adjustments of a dc power supply. Preferably, the voltage of the dc signal is provided at a level that allows the voltage to be maximized without overloading the dc power supply. As the backsputtering process continues, the current in the dc power supply will vary because of changes in the plasma that occur during the backsputtering process. This makes it necessary to adjust the voltage level of the dc signal during the backsputtering process.

The method 600 proceeds next to block 612 where the dc signal and the radio frequency signal are removed and the gas is shut off. The method 600 proceeds next to block 614 where the method ends.

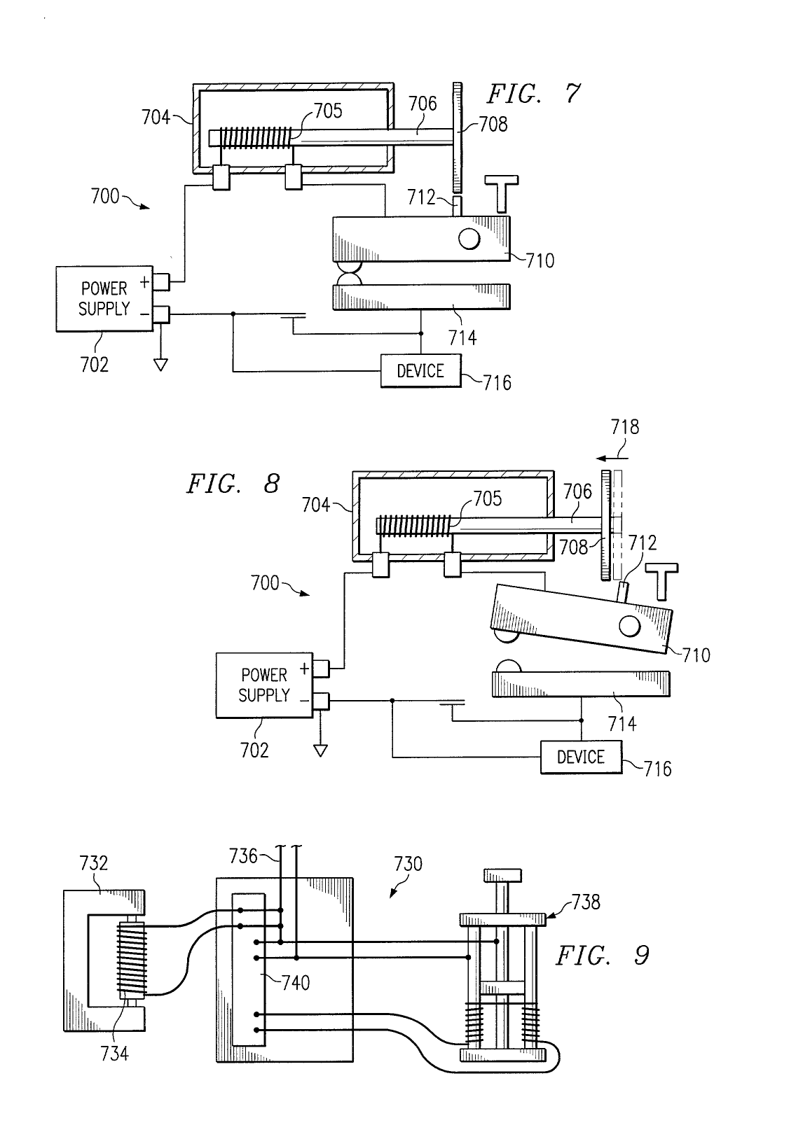

FIG. 7 is a schematic diagram that illustrates a simplified circuit breaker 700 which may be used in, for example, low voltage applications. It should be appreciated from the outset that numerous electronic components and protective electronic devices exist which may benefit from the plasma plating techniques disclosed herein. Various configurations of circuit breakers and circuit breaker components may benefit from the plasma plating techniques and are described for illustrative purposes only and nothing herein is intended or should limit application of the plasma plating techniques to any number or configuration of electronic components or electronic protective devices such as, but not limited to, circuit breakers, protective relays and switches.

A number of these electronic devices and their components may derive great benefit, particularly those utilized in critical applications, such as ensuring the safe shutdown and continued cooling of nuclear reactors and other power plants. The benefits of plasma plating such electronic components include reduced galling, friction and wear reduction, as an improved lubricant, as well as for metallurgical contrast and engineered surface enhancement.

Furthermore, the parts or components of the electronic devices whose surfaces are shown as being provided with the plasma plating are only examples of those found in such components and any number of components or various surfaces may benefit from the techniques and discoveries of the present invention. The specific components and their surfaces are described and detailed herein for illustrative purposes only and in no way should limit the present disclosure. Utilizing the plasma bonding techniques to create the engineered surfaces of the circuit breaker components described hereinafter have resulted in a significant reduction in galling, friction, wear, as well as increased lubrication over an extended period of component use, and are examples of the advantages of utilizing the present invention.

The circuit breaker 700 is an example of a magnetic circuit breaker, although it should be understood that thermal, thermal magnetic, and other circuit breaker configurations may be utilized as well as the magnetic circuit breaker 700. The circuit breaker 700 includes a power supply 702 electrically coupled to a magnetic actuator 704 that includes a magnetic coil 705 electromagnetically communicating with a solenoid plunger 706 having a latch 708 connected at one end. The magnetic actuator 704 is electrically coupled to an actuator 710.

It can be seen that a portion 712 of the actuator 710 engages a portion of the latch 708 of the solenoid plunger 706 which causes the actuator 710 to maintain its position in contact with a lower portion 714 of the actuator 710. The lower portion 714 of the actuator 710 electrically communicates with the device 716 to be powered as well as communicating with the power supply 702.

FIG. 8 illustrates the circuit breaker 700 in a tripped condition. It is readily apparent that as the current provided by the device exceeds a predetermined level, the magnetic field generated by the magnetic coil 705 becomes strong enough to reach a predetermined rate desirous for a particular type of circuit breaker and the solenoid plunger 706 is caused to move longitudinally in a direction 718. As the solenoid plunger 706 moves, the latch 708 disengages the portion 712 of the actuator 710 allowing the actuator 710, which may be pivotally mounted and under magnetic or mechanical force, to move out of contact with the lower portion 714 of the actuator 710.

The disengagement of the actuator 710 with the lower portion 714 of the actuator 710 disconnects the circuit when the current exceeds a predetermined rate of the circuit breaker 700. It will be appreciated that a number of surfaces of the circuit breaker 700 may be subject to galling, friction, and wear, and require lubrication to maintain the effectiveness of the circuit breaker 700 to control the current rating of the circuit breaker 700. These surfaces may include but are not limited to the solenoid plunger 706, the latch 708, the magnetic coil 705, the actuator 710, the portion 712 of the actuator 710, and the lower portion 714 of the actuator 710. In some aspects, only particular surfaces of these components may be preferably plasma plated to achieve the advantages and overcome the shortcomings of previously implemented techniques.

FIG. 9 illustrates a circuit breaker tripping system 730 which may be implemented in an industrial application where the current loads and voltage are much greater than those where the circuit breaker 700, previously discussed, would be implemented. The circuit breaker tripping system 730 is similar to those manufactured by Westinghouse, Type DS and DSL circuit breakers, for example.

The circuit breaker tripping system 730 includes a sensor 732 provided with a magnetic coil 734 to determine the current level. The sensor 732 communicates with an electrical communication line 736 providing power to devices for which the circuit breaker protects from over or undercurrent. The circuit breaker tripping system 730 includes a trip actuator 738 that communicates with the electrical communication line 736 and is coupled as a switch operable to disconnect the electrical communication line 736. The trip actuator 738, the sensor 732 and the electrical communication line 736 are coupled to a trip unit 740.

The trip unit 740 is operable to communicate with the sensor 732 and determine whether an overcurrent state of the electrical communication line 736 has been detected by the sensor 732. The trip unit 740 is coupled to the trip actuator 738 electro-mechanically such that the trip unit 740 may cause the trip actuator 738 to electro-mechanically disconnect the electrical communication line 736 when an overcurrent state has been detected by the sensor 732. The circuit breaker tripping system 730 is used herein for illustrative purposes only and a number of circuit breakers and circuit breaker tripping systems are well known in the art and are used in a variety of industrial and other applications for the purposes of monitoring current and other protective electrical reasons.

FIG. 10 illustrates a perspective view of a circuit breaker 750 that may utilize the circuit breaker tripping system 730 as previously described in FIG. 9 above. The circuit breaker 750 may include a power operating mechanism 752 in communication with a levering mechanism 754. The power operating mechanism 752 further communicates with a pole shaft 756 and a closing spring 758.

The circuit breaker tripping system 730, illustrated in FIG. 9, and the circuit breaker 750 are illustrative of circuit breakers utilized for these purposes which may benefit from the plasma plating techniques disclosed and described herein.

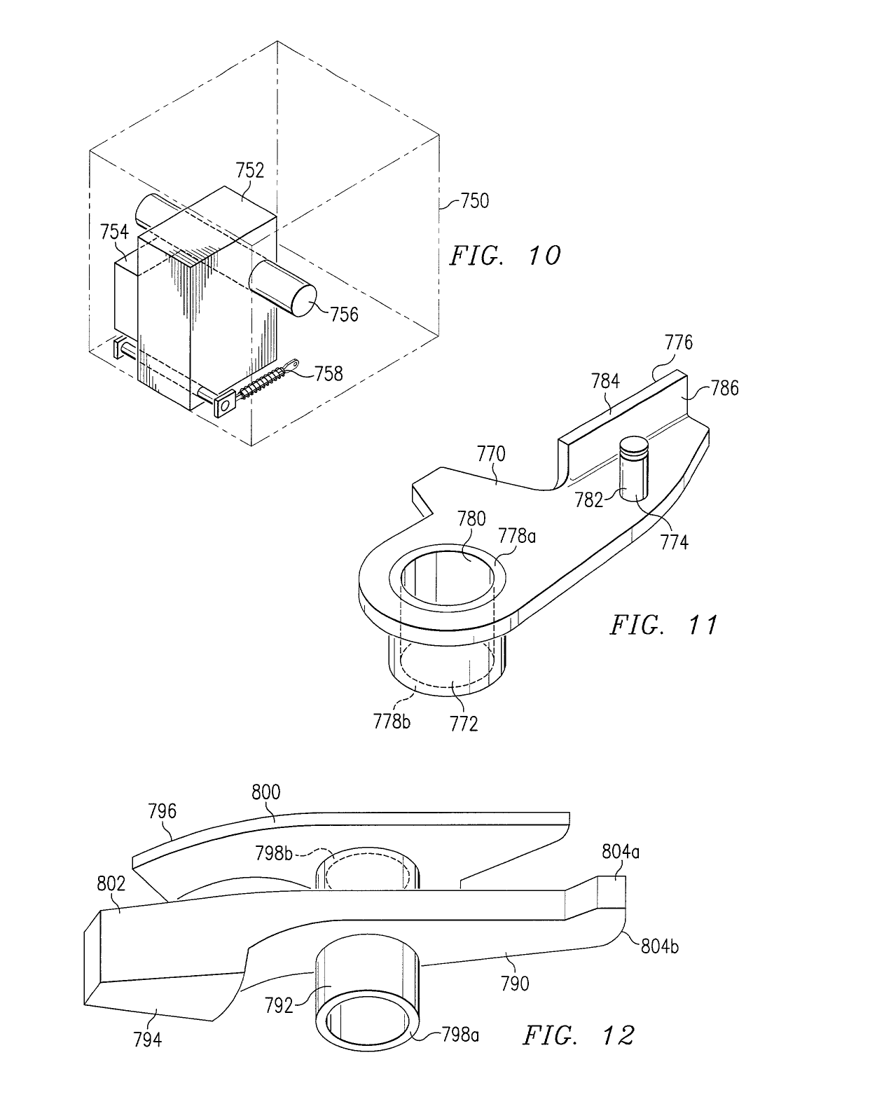

FIGS. 11 and 12 illustrate components which may comprise a portion of the assembly (not shown) of the closing spring 758 which may be plasma plated in accordance with one aspect of the present invention. FIG. 11 illustrates an oscillator 770 portion of the closing spring 758 and is provided with a cylindrical member 772 extending through a portion of the oscillator 770. The oscillator is further provided with a pin 774 extending from a surface of the oscillator 770 and a flange 776 extending from one edge of the oscillator 770.

According to one aspect, the plasma plating technique disclosed and described herein may be beneficially provided on ends 778a and 778b of the cylindrical member 772 as well as on an inner surface 780 of the cylindrical member 772. Other components that may benefit from the engineered surface enhancement of the plating techniques described herein include a surface 782 of the pin 774 as well as a first and second sides 784 and 786 of the flange 776. It will appreciated that certain surfaces of electrical components are subjected to greater wear, friction, galling and other detrimental effects of electric and electromechanical activity.

Although portions of the cylindrical member 772, the pin 774 and the flange 776 are plated with the plasma plating according to the present aspect, it will be appreciated that in other aspects various other portions of the oscillator 770 may be plated, while yet in other aspects the entirety of the oscillator 770 may be benefit from being plasma plated.

FIG. 12 illustrates a spring release latch 790 which may be another component of the closing spring 758, illustrated in the circuit breaker 750, in FIG. 10 above. The spring release latch 790 includes a cylindrical member 792, a main portion 794 and a lateral portion 796. Ends 798a and 798b of the cylindrical member 792 may benefit from the plasma plating as may an upper surface 800 of the lateral portion 796 of the spring release latch 790.

Furthermore, an upper first end 802 and an upper and lower second ends 804a and 804b, respectively, of the main portion 794 may also benefit from the plasma plating. It will be appreciated that such surfaces are subjected to considerable movement and contact with adjacent components which may cause convention lubricants to glue or gum or may cause the surfaces to gall or become glued to adjacent components. The advantage of plasma plating the described surfaces is to prevent galling, friction, and reduce wear on the plated surfaces as well as to act as a more effective and long lasting lubricant that will not glue or bond to adjacent surfaces over time.

As previously discussed, although a number of surfaces are described herein as being preferably plasma plated, any number or combination of surfaces may be plated to achieve the benefits described and disclosed herein and the spring release latch 790 may be plated in its entirety according to other aspects. It should also be appreciated that the wide variety of circuit breakers, relays and switches are provided with an almost infinite number of various configurations and component structures having various surfaces which may benefit from the plasma plating techniques disclosed and described herein and which will not be discussed further for purposes of brevity.

It is within the spirit and scope of the present invention that any component or components, sets or groups of components, surfaces of particular components and combination of surfaces and complete plating of components of the numerous types of circuit breakers, relays, and switches, be implanted with various depositants for the purposes of antigalling, friction reduction, wear reduction, lubrication, metallurgical contrast and engineered surface enhancement. It is further within the spirit and scope of the present invention that any number or combination of depositants may be utilized for these purposes.

Thus, it is apparent that there has been provided, in accordance with the present invention, a system and method for plasma plating electronic components, such as, but not limited to, circuit breakers, that satisfies one or more of the advantages set forth above. Although the preferred embodiment has been described in detail, it should be understood that various changes, substitutions, and alterations can be made herein without departing from the scope of the present invention, even if all, one, or some of the advantages identified above are not present. For example, the dc signal and the radio frequency signal may be electrically coupled to the substrate using virtually any available electrically conductive path. The present invention may be implemented using any of a variety of materials and configurations. For example, any of a variety of vacuum pump systems, equipment, and technology could be used in the present invention. The present invention also does not require the presence of a gas, such as argon, to form a plasma, and the backsputtering process is not a mandatory process to practice the present invention. These are only a few of the examples of other arrangements or configurations of the system and method that are contemplated and covered by the present invention.

The various components, equipment, substances, elements, and processes described and illustrated in the preferred embodiment as discrete or separate may be combined or integrated with other elements and processes without departing from the scope of the present invention. The present invention may be used to plasma plate virtually any material, object, or substrate using any of a variety of depositants. Other examples of changes, substitutions, and alterations are readily ascertainable by one skilled in the art and could be made without departing from the spirit and scope of the present invention.

What is claimed is:

1. A method for plasma plating a portion of a circuit breaker component to prevent circuit breaker failure, the method comprising:
positioning the circuit breaker component of a circuit breaker within a vacuum chamber;
positioning a depositant in an evaporation source within the vacuum chamber;
applying a dc signal to the circuit breaker component;
applying a radio frequency signal to the circuit breaker component; and
heating the depositant to a temperature at or above the melting point of the depositant to generate a plasma in the vacuum chamber.

2. The method of claim 1, further comprising:
reducing the pressure in the vacuum chamber to a level at or below 4 milliTorr; and
introducing a gas into the vacuum chamber at a rate to raise the pressure in the vacuum chamber to a level at or between 0.1 milliTorr and 4 milliTorr.

3. The method of claim 2, wherein applying the dc signal to the circuit breaker component includes applying the dc signal to the circuit breaker component at a voltage amplitude at or between 1 volt and 5000 volts and wherein applying the radio frequency signal to the circuit breaker component further includes applying a radio frequency signal to the circuit breaker component at a power level at or between 1 watt and 50 watts.

4. The method of claim 3, wherein reducing the pressure in the vacuum chamber to the level at or below 4 milliTorr includes reducing the pressure in the vacuum chamber to the level at or below 1.5 milliTorr, and wherein introducing the gas into the vacuum chamber at a rate to raise the pressure in the vacuum chamber to the level at or between 0.1 milliTorr and 4 milliTorr includes introducing the gas into the vacuum chamber at a rate to raise the pressure to a level at or between 0.5 milliTorr and 1.5 milliTorr.

5. The method of claim 3, wherein applying the dc signal to the circuit breaker component at the voltage amplitude at or between 1 volt and 5000 volts includes applying the dc signal to the circuit breaker component at the voltage level at or between negative 500 volts and negative 750 volts.

6. The method of claim 1, wherein applying the radio frequency signal to the circuit breaker component at the power level at or between 1 watt and 50 watts includes applying the radio frequency signal to the circuit breaker component at the power level at or between 5 watts and 15 watts.

7. The method of claim 1, wherein the depositant is a metal.

8. The method of claim 1, wherein the depositant is a metal alloy.

9. The method of claim 1, wherein the depositant is gold.

10. The method of claim 1, wherein the depositant is titanium.

11. The method of claim 1, wherein the depositant is chromium.

12. The method of claim 1, wherein the depositant is nickel.

13. The method of claim 1, wherein the depositant is silver.

14. The method of claim 1, wherein the depositant is tin.

15. The method of claim 1, wherein the depositant is indium.

16. The method of claim 1, wherein the depositant is lead.

17. The method of claim 1, wherein the depositant is copper.

18. The method of claim 1, wherein the depositant is palladium.

19. The method of claim 1, wherein the depositant is a silver/palladium metal alloy.

20. The method of claim 1, wherein the depositant is carbon.

21. The method of claim 1, wherein the depositant is a nonmetal

22. The method of claim 1, wherein the depositant is a ceramic.

23. The method of claim 1, wherein the depositant is a metal carbide.

24. The method of claim 1, wherein the depositant is a metal nitride.

25. The method of claim 1, wherein the depositant is provided in a form from the class consisting of a pellet, a wire, a granule, a powder, a ribbon, and a strip.

26. The method of claim 1, wherein the gas is argon and the despositant is a metal allow of silver/palladium, and the plasma includes argon ions and silver/palladium ions.

27. The method of claim 1, wherein the circuit breaker component is at least a first surface of a levering mechanism of a circuit breaker.

28. The method of claim 1, wherein the circuit breaker component is at least a first surface of a closing spring portion of a circuit breaker.

29. The method of claim 1, wherein the circuit breaker component is at least a first surface of a trip mechanism of a circuit breaker.

30. A method for plasma plating protective electronic components, the method comprising:
positioning a protective electronic component within a vacuum chamber;
positioning a depositant in an evaporation source within the vacuum chamber;
reducing the pressure in the vacuum chamber to a level at or between 0.1 milliTorr and 4 milliTorr;
applying a dc signal to the protective electronic component at a voltage amplitude at or between 1 volt and 5000 volts;
applying a radio frequency signal to the protective electronic component at a power level at or between 1 watt and 50 watts; and
heating the depositant to a temperature at or above the melting point of the depositant to generate a plasma in the vacuum chamber.

31. The method of claim 29, wherein the protective electronic component is further defined as an electrical relay component.

32. The method of claim 30, wherein a surface of the electrical relay component is plasma plated to prevent galling.

33. The method of claim 30, wherein a surface of the electrical relay component is plasma plated for lubrication.

34. The method of claim 30, wherein a surface of the electrical relay component is plasma plated to resist wear.

35. The method of claim 29, wherein the protective electronic component is further defined as an electrical switch component.

36. The method of claim 34, wherein a surface of the electrical switch component is plasma plated to prevent galling.

37. The method of claim 34, wherein a surface of the electrical switch component is plasma plated for lubrication.

38. The method of claim 34, wherein a surface of the electrical switch component is plasma plated to resist wear.

39. The method of claim 29, wherein the protective electronic component is further defined as a circuit breaker component.

40. The method of claim 38, wherein a surface of the circuit breaker component is plasma plated to prevent galling.

41. The method of claim 38, wherein a surface of the circuit breaker component is plasma plated for lubrication.

42. The method of claim 38, wherein a surface of the circuit breaker component is plasma plated to resist wear.

43. A method of manufacturing protective electronic components with plasma plating, the method comprising:
positioning a protective electronic component within a vacuum chamber;
positioning a depositant within the vacuum chamber;
heating the depositant to a temperature at or above the melting point of the depositant to generate a plasma in the vacuum chamber; and
implanting the depositant on at least a surface of the electronic component within the vacuum chamber.

44. The method of claim 42, wherein the surface of the protective electronic component is plasma plated to prevent galling.

45. The method of claim 42, wherein the surface of the protective electronic component is plasma plated for lubrication.

46. The method of claim 42, wherein the surface of the protective component is plasma plated to resist wear.

47. The method of claim 42, wherein the surface of the protective component is plasma plated for metallurgical contrast.

48. The method of claim 42, wherein the surface of the protective component is plasma plated for engineered surface enhancement.

49. A circuit breaker for preventing overcurrent in an electrical communication line, the circuit breaker comprising:
a sensor in communication with the electrical communication line and operable to sense a current level of the electrical communication line; and
a trip mechanism operably coupled to the electrical communication line to disconnect a portion of the communication line, the trip mechanism having a plurality of component surfaces, at least a first surface of the plurality of component surfaces of the trip mechanism provided with an engineered surface.

50. The circuit breaker of claim 49, wherein the engineered surface is further defined as implanted with a depositant.

51. The circuit breaker of claim 50, wherein the depositant is implanted utilizing a dc signal and a radio frequency applied to the at least first surface of the trip mechanism.

52. The circuit breaker of claim 51, wherein the sensor is provided with a plurality of component surfaces, at least a first surface of the plurality of component surfaces of the sensor provided with an engineered surface implanted with a depositant utilizing a dc signal and a radio frequency applied to the at least first surface of the trip mechanism.
